(19) United States
(12) Patent Application Publication
(10) Pub. No.: US 2026/0162850 A1
(43) Pub. Date: Jun. 11, 2026

(54) SLITTED FLEXIBLE PRINTED CIRCUIT TO IMPROVE CROSSTALK

(71) Applicant: International Business Machines Corporation, Armonk, NY (US)

(72) Inventors: Layne A. Berge, Windsor, CO (US); Sean Hart, Tarrytown, NY (US); Lixin Guo, Byron, MN (US); Young Hoon Kwark, Chappaqua, NY (US); DAVID LOKKEN-TOYLI, White Plains, NY (US); Corrado P Mancini, Hopewell Junction, NY (US); Michael Karunendra Selvanayagam, Ossining, NY (US); Duixian Liu, Scarsdale, NY (US)

(21) Appl. No.: 18/963,890

(22) Filed: Nov. 29, 2024

(51) Int. Cl. H01B 11/00; H05K 7/20

(52) U.S. Cl. CPC H01B 11/00; H05K 7/20372

(57) ABSTRACT

A radio frequency cable includes a first signal trace on a first signal layer of the radio frequency cable, a first dielectric layer residing under the first signal layer and a first reference ground plane residing under the first dielectric layer of the printed circuit radio frequency cable. The first dielectric layer separates the first reference ground plane and the first signal layer, the first reference ground plane having one or more slits defined therein, each slit running parallel to the first signal trace.

### BACKGROUND

The present invention relates generally to the electrical, electronic and computer arts and, more particularly, to quantum electronics and devices.

In quantum computing, flex cables and coaxial cables are conventionally used for delivering a variety of signals used for controlling qubits, including radio frequency (RF) pulses, baseband pulses, direct current (DC) biases, and the like. Crosstalk between signals on neighboring channels, including far-end crosstalk (FEXT), may impact the performance of the quantum computing system, especially two-qubit gate fidelity. (Far-end crosstalk may be normalized based upon the insertion loss of the channel (EL-FEXT).) Coaxial cables conventionally provide acceptable crosstalk levels; however, to scale to higher qubit counts, coaxial wiring is being replaced with higher density and lower cost cabling solutions.

### BRIEF SUMMARY

Principles of the invention provide systems and techniques for a slitted flexible printed circuit to improve crosstalk.

In one aspect, a radio frequency cable comprises a first signal trace on a first signal layer of the radio frequency cable; a first dielectric layer residing under the first signal layer; and a first reference ground plane residing under the first dielectric layer of the printed circuit radio frequency cable, the first dielectric layer separating the first reference ground plane and the first signal layer, the first reference ground plane having one or more slits defined therein, each slit running parallel to the first signal trace.

In one aspect, a quantum computing system comprises a control electronics system; a cryogenic quantum device; and a signal delivery assembly between the control electronics system and the cryogenic quantum device, the signal delivery assembly comprises a first signal trace on a first signal layer of the radio frequency cable; a first dielectric layer residing under the first signal layer; and a first reference ground plane residing under the first dielectric layer of the printed circuit radio frequency cable, the first dielectric layer separating the first reference ground plane and the first signal layer, the first reference ground plane having one or more slits defined therein, each slit running parallel to the first signal trace.

As used herein, “facilitating” an action includes performing the action, making the action easier, helping to carry the action out, or causing the action to be performed. Thus, by way of example and not limitation, instructions executing on a processor might facilitate an action carried out by a remote processor, by semiconductor and electronic fabrication equipment, or the like, by sending appropriate data or commands to cause or aid the action to be performed. Where an actor facilitates an action other than by performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1A is a high-level diagram for a conventional cryostat supporting a quantum processor;

FIG. 1B is a plot illustrating FEXT vs. frequency measured on two neighboring differential traces when the traces reside on copper-nickel alloy (CuNi) reference ground planes or copper reference ground planes;

FIG. 2A illustrates a configuration (top view) of a flex cable featuring differential signal pairs, in accordance with example embodiments;

FIG. 2B illustrates a configuration (top view) of a flex cable featuring single-ended signals, in accordance with example embodiments;

FIG. 3A illustrates the CuNi reference ground planes having slits (cross-section view), in accordance with example embodiments;

FIG. 3B illustrates that the CuNi reference ground planes slits are covered with CuNi (cross-section view), in accordance with example embodiments;

FIG. 3C illustrates the CuNi reference ground planes having slits where the planes are two times thicker than the embodiments of FIG. 3A and FIG. 3B (cross-section view), in accordance with example embodiments;

FIG. 3D illustrates a cross-sectional view of a single CuNi reference ground plane having slits, in accordance with example embodiments;

FIG. 4 is a plot illustrating the improvement to crosstalk at low frequency attained by using reference ground plane slits, in accordance with example embodiments;

FIG. 5 is a graph comparing crosstalk for different embodiments, in accordance with example embodiments;

FIG. 6 is a graph comparing crosstalk for different embodiments, in accordance with example embodiments;

FIG. 7 is a graph comparing crosstalk for different embodiments, in accordance with example embodiments;

FIG. 8 depicts a computing environment according to an embodiment of the present invention;

FIG. 9 is a flow diagram of a design process used in semiconductor design, manufacture, and/or test.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary radio frequency cable 252 comprises a first signal trace 256-1, 280-1 on a first signal layer of the radio frequency cable 252; a first dielectric layer 276-2 residing under the first signal layer; and a first reference ground plane 261-1, 261-2 residing under the first dielectric layer 276-2 of the printed circuit radio frequency cable 252, the first dielectric layer 276-2 separating the first reference ground plane 261-1, 261-2 and the first signal layer, the first reference ground plane 261-1, 261-2 having one or more slits 268 defined therein, each slit 268 running parallel to the first signal trace 256-1, 280-1. Technical benefits include a cable for quantum processing systems that reduces crosstalk relative to typical flex cables while addressing thermal conductivity requirements of cryostats; a cable for quantum processing systems that potentially has application for superconducting qubit architectures, spin qubit architectures using near-DC (direct current) pulses and other architectures; a cable for quantum processing systems characterized by slit reference ground planes that provide isolation between the differential signal pairs that are used to control, for example, tunable couplers; an improvement by more than 10 decibels (dB) in the EL-FEXT in the frequency band of interest; and reduced cost and increased density relative to conventional coaxial cabling solutions.

In example embodiments, a second dielectric layer 276-1 resides over the first signal layer and a second reference ground plane 260-1, 260-2 resides over the second dielectric layer 276-1 of the radio frequency cable 252, the second reference ground plane 260-1, 260-2 having one or more slits 268 defined therein, each slit 268 running parallel to the first signal trace 256-1, 280-1. Technical benefits include benefits of claim 1 in a stripline configuration.

In example embodiments, the first reference ground plane 261-1, 261-2 and the second reference ground plane 260-1, 260-2 are implemented using CuNi. Technical benefits include benefits of claim 1 using an exemplary material for the reference ground planes.

In example embodiments, one or more vias 264 couple the first reference ground plane 261-1, 261-2 to the second reference ground plane 260-1, 260-2 to prevent resonant modes between the first reference ground plane 261-1, 261-2 and the second reference ground plane 260-1, 260-2. Technical benefits include using vias 264 to further enhance the crosstalk reduction and prevent resonant modes between the first reference ground plane 261-1, 261-2 and the second reference ground plane 260-1, 260-2.

In example embodiments, a second signal trace 256-2 is on the first signal layer of the radio frequency cable 252, the second signal trace 256-2 running parallel to the first signal trace 256-1 and the first signal trace 256-1 and the second signal trace 256-2 constituting a differential signal pair. Technical benefits include the benefits of claim 1 with the use of differential signals.

In example embodiments, a third signal trace 256-1 is on a second signal layer residing above the second reference ground plane 260-1, 260-2 of the radio frequency cable 252; and a third reference ground plane 260-1, 260-2 residing above the second signal layer of the radio frequency cable 252, the third reference ground plane 260-1, 260-2 comprising one or more slits 268, each slit 268 running parallel to the corresponding third signal trace 256-1. Technical benefits include a reduction of crosstalk in a high-density signal environment.

In example embodiments, the radio frequency cable 252 is implemented as one of a microstrip, a stripline and a co-planar waveguide. Technical benefits include a reduction of crosstalk using microstrip, stripline and co-planar waveguide implementations.

In example embodiments, additional first signal traces 256-1, 280-1 are on the first signal layer. Technical benefits include a reduction of crosstalk in a high-density signal environment.

In another aspect, a quantum computing system comprises a control electronics system 238; a cryogenic quantum device 248; and a signal delivery assembly 212 between the control electronics system 238 and the cryogenic quantum device 248, the signal delivery assembly 212 comprising a first signal trace 256-1, 280-1 on a first signal layer of the radio frequency cable 252; a first dielectric layer 276-2 residing under the first signal layer; and a first reference ground plane 261-1, 261-2 residing under the first dielectric layer 276-2 of the printed circuit radio frequency cable 252, the first dielectric layer 276-2 separating the first reference ground plane 261-1, 261-2 and the first signal layer, the first reference ground plane 261-1, 261-2 having one or more slits 268 defined therein, each slit 268 running parallel to the first signal trace 256-1, 280-1. Technical benefits include a reduction of crosstalk in a quantum computing system operating at cryogenic temperatures.

In example embodiments, a cryogenic system is configured to cool the cryogenic quantum device 248 and the signal delivery assembly 212 transmits signals between two or more temperature stages of the cryogenic system. Technical benefits include a reduction of crosstalk in a quantum computing system operating at cryogenic temperatures.

In example embodiments, the cryogenic quantum device 248 is a superconducting quantum processor. Technical benefits include a reduction of crosstalk in a superconducting quantum computing system configured to perform quantum calculations.

In example embodiments, the non-superconducting cables with the slits 268 are concatenated with superconducting cables 242 as part of the signal delivery assembly 212. Technical benefits include the support of high performance two-qubit gates in quantum processing systems using tunable couplers and enabling the use of high fidelity simultaneous two-qubit gates

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
a cable for quantum processing systems that reduces crosstalk relative to typical flex cables while addressing thermal conductivity requirements of cryostats;
a cable for quantum processing systems that potentially has application for superconducting qubit architectures, spin qubit architectures using near-DC (direct current) pulses and other architectures;
a cable for quantum processing systems characterized by slit reference ground planes that provide isolation between the differential signal pairs that are used to control, for example, tunable couplers;
an improvement by more than 10 decibels (dB) in the EL-FEXT in the frequency band of interest;
support of high performance two-qubit gates in quantum processing systems using tunable couplers and enabling the use of high fidelity simultaneous two-qubit gates; and
reduced cost and increased density relative to conventional coaxial cabling solutions.

Generally, a configuration for a cable with reduced crosstalk is disclosed. The configuration can be applied, for example, to a flex cable for use in qubit architectures. (Exemplary techniques are also potentially applicable to spin qubit architectures using baseband pulses and other architectures, in addition to superconducting qubit architectures.) To scale to higher qubit counts, coaxial wiring is being replaced with a higher density solution. Flex (ribbon) wiring allows for more than an order of magnitude increase in density over coaxial wiring. Such high density wiring solutions are required to support the heterogenous signals controlling qubits, tunable couplers, cryogenic electronics, and related devices.

In some tunable coupler architectures, a relatively low speed pulse is applied to the tunable coupler to control it. This low-speed pulse has broad frequency content from “DC” to ˜100 megahertz (MHz) and is highly susceptible to crosstalk. The crosstalk in this band is quite pertinent to allow for simultaneous 2Q gates to operate properly. To deliver these signals from room temperature to the chip in the cryostat, both single-ended and differential signaling schemes can be used.

In example embodiments, a copper-nickel (CuNi) alloy is used to implement the reference ground plane to reduce thermal conductivity between stages of the cryostat. (It is noted that other low-thermal conductivity materials can be utilized.) In accordance with the Wiedemann-Franz law, the low thermal conductivity is associated with low electrical conductivity. This latter characteristic results in increased crosstalk when using CuNi reference ground planes (vs. copper (Cu) reference ground planes).

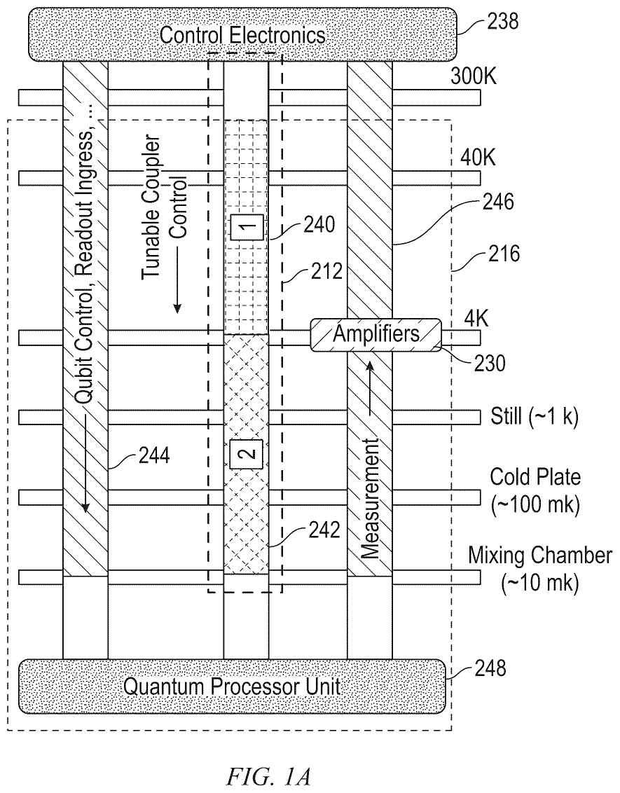

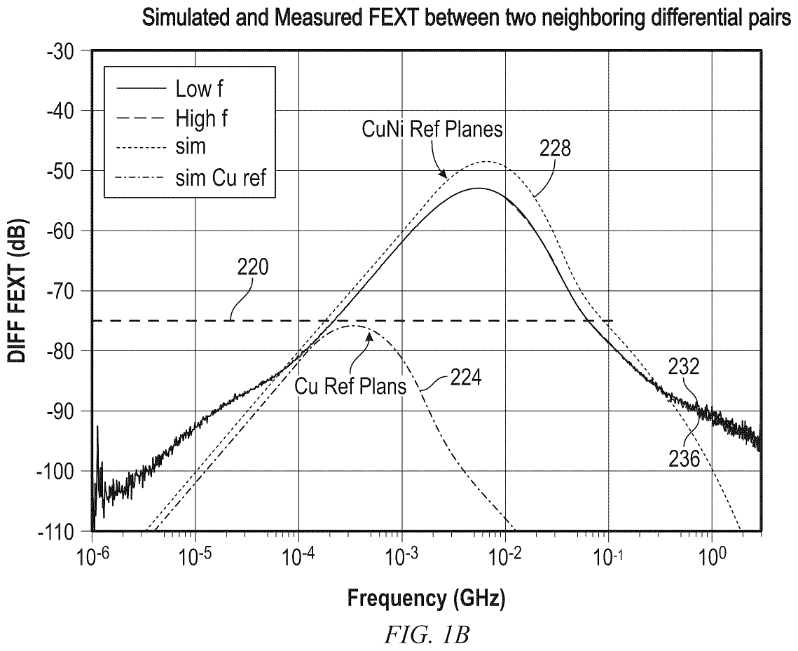

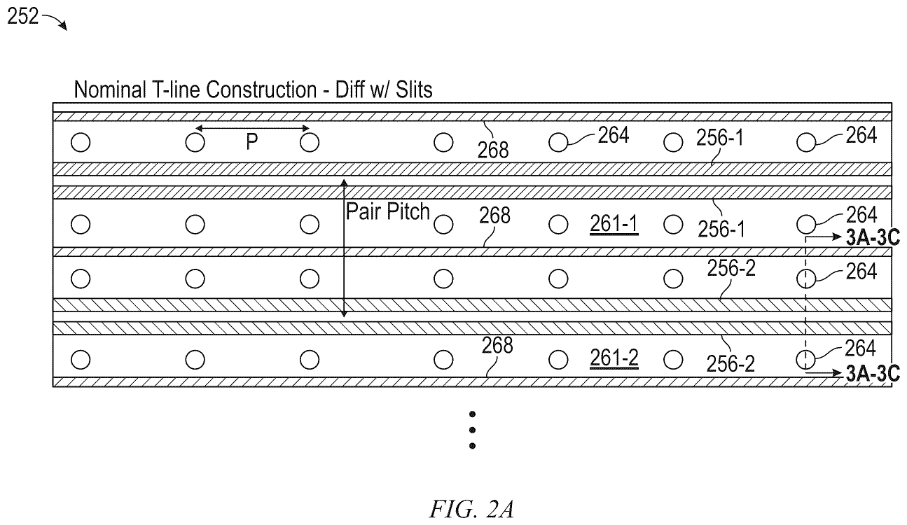

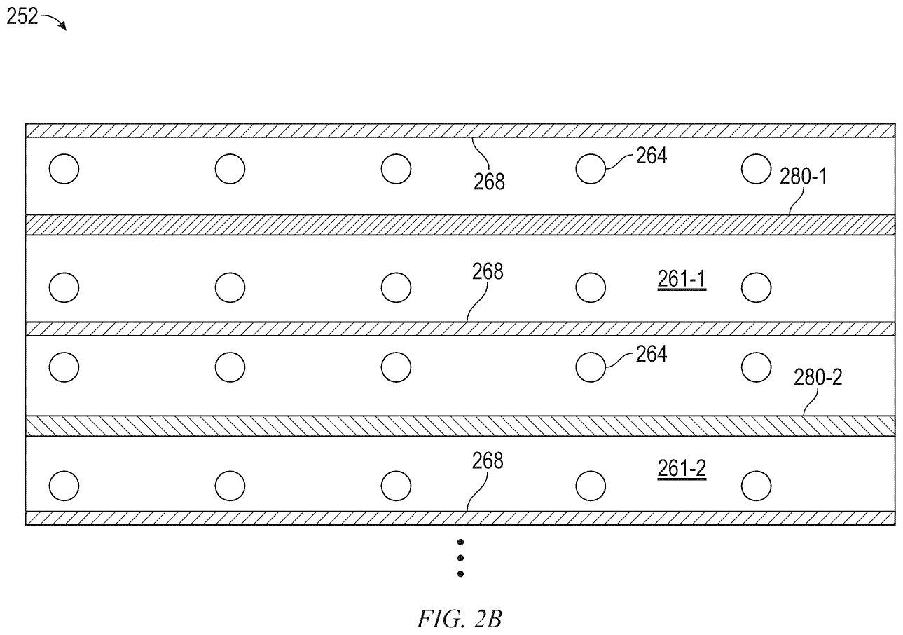

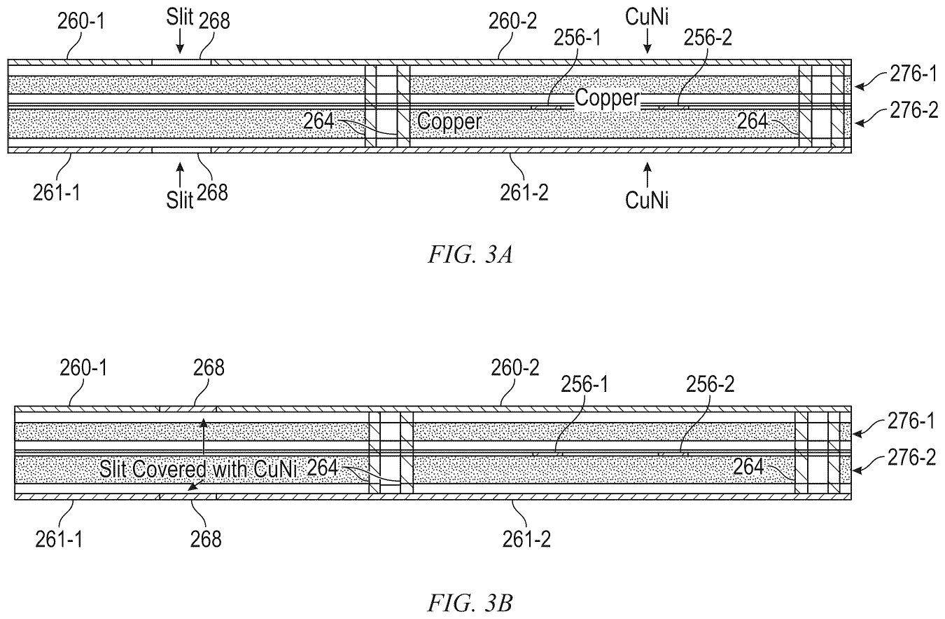

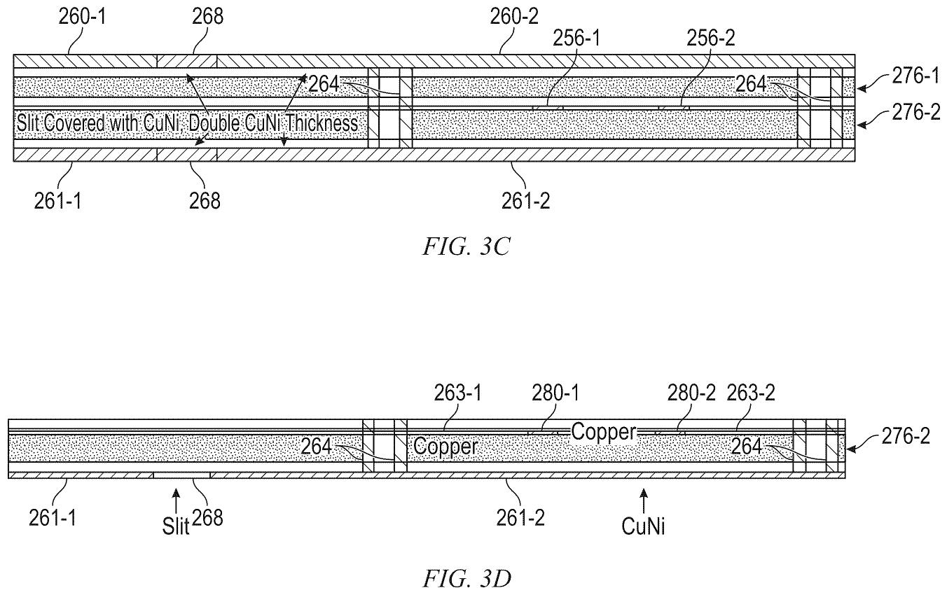

FIG. 1A is a high-level diagram for a conventional cryostat 216 supporting a quantum processor unit 248. A quantum processor unit 248 in the cryostat 216 includes a plurality of qubit circuits configured to run quantum gates under the control of control electronics 238. It is noted that, in example embodiments, control electronics 238 are operating at room temperature, as indicated by the 300 Kelvin (K) reference, while the quantum processor unit 248 is operating at cryogenic temperatures, as indicated by the ˜10 mK reference. Note, however, that in other embodiments, control electronics 238 could operate at cryogenic temperatures or an intermediate temperature. Signals, such as tunable coupler control signals, are carried over a signal carrier system 212. In example embodiments, the signal carrier system 212 is implemented with superconducting cables 242, as illustrated in FIG. 1A, in combination with non-superconducting carriers 240, such as the carriers illustrated in FIGS. 2A-3D. In example embodiments, the signal carrier system 212 is implemented with non-superconducting carriers 240.

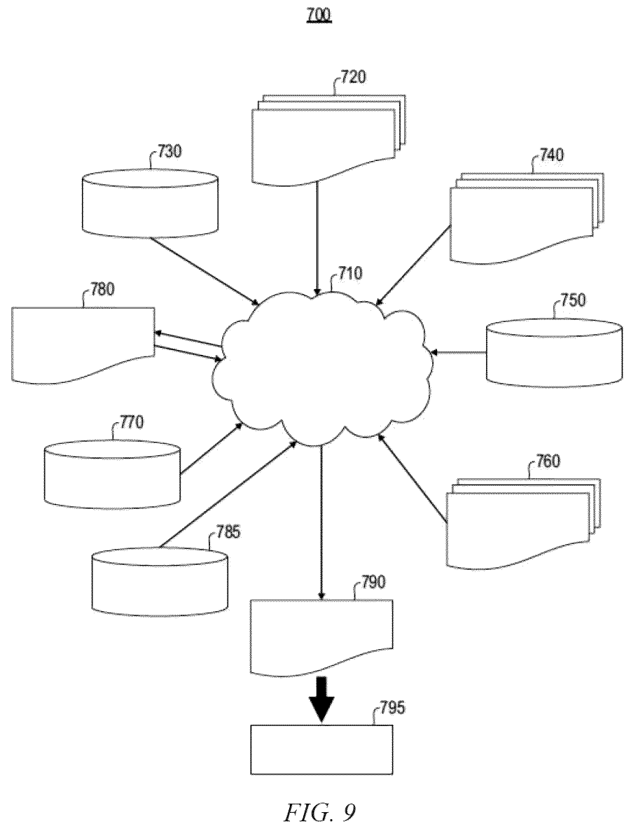

Given the teachings herein, the skilled artisan will be able to provide the control electronics 238 by adapting known techniques (e.g., in digital circuitry). To implement digital circuitry, computer-aided semiconductor integrated circuit (IC) logic design, simulation, test, layout, and/or manufacture can be employed, as discussed below with respect to FIG. 9. The skilled artisan can synthesize digital logic circuits to carry out desired control and other functionality, using known computer-aided design techniques. The control electronics 238 carry out functions as defined herein; given the teachings and description of the functions herein, known control circuit technologies can be employed; e.g., multicycle or pipelined, hardwired or microprogrammed, using any suitable technology family (e.g., 7 nm CMOS, 5 NM CMOS, and the like). For example, the specified functions can be instantiated in logic circuitry using a known design flow process used for example, in semiconductor IC logic design, simulation, test, layout, and manufacture.

Qubit control and readout ingress signals 244 are transferred from the control electronics 238 to the quantum processor unit 248. (Qubit control and readout ingress signals 244 can be carried, for example, by flex cables, coaxial cables, and the like.) Measurement signals from the quantum processor unit 248 are transferred from the quantum processor unit 248 to the control electronics 238 via amplifiers 230, which are operating at 4K.

FIG. 1B is a plot illustrating FEXT vs. frequency measured on two neighboring differential traces when the traces reside on copper-nickel alloy (CuNi) reference ground planes or copper reference ground planes. For tunable coupler architectures, crosstalk, even at notionally small levels of approximately −80 Decibels (dB) in the bands of interest, may be deleterious to gate fidelities and overall device performance; that is, where the low-speed quantum signal pulses reside (typically from direct current (DC) to the tens of MHz range, as indicated by the bold dashed horizontal line 220). Copper signal traces and copper ground planes typically approach the crosstalk goal of less than −80 dB, as indicated by the dotted line 224. While copper meets the crosstalk requirement, it has substantially more thermal conductivity than other conductors and therefore is less advantageous for transitioning between the multiple temperature stages in the cryostat of a quantum processing system as it adds an extra heat load on colder temperature stages. While other conductive materials, such as CuNi, provide better thermal conductivity characteristics (which is desirable since the cable typically spans multiple temperature stages in the cryostat), such materials suffer from higher levels of crosstalk when used as reference ground planes for the signal traces in, for example, flex cables. As illustrated in FIG. 1B, the utilization of CuNi reference ground planes and copper signal traces provide higher crosstalk values in simulations (dotted lines 224 vs 228; lines 232 and 236 represent measured data on a real flex cable). Moreover, the crosstalk peaks at higher frequencies (in the bands of interest where the low-speed pulses reside; that is, in the tens of MHz range for CuNi).

### Exemplary Solution

FIG. 2A illustrates a configuration (top view) of a flex cable 252 featuring differential signal pairs 256-1, 256-2, in accordance with example embodiments. The flex cable 252 includes pairs of patterned signal traces 256-1, 256-2. In example embodiments, the flex cable 252 includes a layer of a flexible dielectric (such as a polyimide; see dielectric layers 276-1, 276-2) that forms a flexible backbone for the flex cable 252. Each pair of patterned signal traces 256-1, 256-2 constitutes a differential signal pair. While two differential pairs of patterned signal traces 256-1, 256-2 are explicitly represented in FIG. 2, an arbitrary number of differential pairs per cable is contemplated. In example embodiments, CuNi, a low thermal conductivity material, is used for the reference ground planes 261-1, 261-2 that reside above (in some embodiments) and below the signal traces 256-1, 256-2 to help control thermal conductivity. Copper, for example, is used for the signal traces, such as the differential signal traces 256-1, 256-2. (Other conductors, such as gold, silver, various alloys and the like can also be utilized.) Unfortunately, this comes with poor low-frequency behavior (as shown in the plot of FIG. 1B) due to the poor electrical conductivity of the CuNi material. This low-frequency crosstalk effect would be prevalent for any flex wiring solution that uses low thermal conductivity/low electrical conductivity materials for the reference ground planes 261-1, 261-2.

It is noted that, in example embodiments, reference ground planes 260-1, 260-2 also reside above the signal traces 256-1, 256, as illustrated in FIGS. 3A-3C. In example embodiments, the reference ground planes 260-1, 260-2, 262-1, 261-2 that reside above and below the signal traces 256-1, 256 are connected by vias 264, as illustrated in FIGS. 3A-3C. Moreover, additional layers of signal traces 256-1, 256-2 and layers of reference ground planes 260-1, 260-2, 262-1, 261-2 can be stacked to create a flex cable having a plurality of signal trace layers interleaved with reference ground plane layers. In this case, each signal trace layer will have reference ground planes 260-1, 260-2, 262-1, 261-2 above and below the corresponding signal trace layer. Each pair of reference ground planes 260-1, 260-2, 262-1, 261-2 in the multi-layer configuration can be connected by corresponding vias 264. It is noted that, in example embodiments, there is no reference ground plane above the top signal layer or below the bottom signal layer. Also, in example embodiments, printed circuit technology is used to manufacture the flex cable 252.

To reduce crosstalk, reference ground plane slits 268 are integrated between pairs of the differential signal traces 256-1, 256-2. The slits 268 can be created using lithography/etching, liftoff, laser ablation, milling, and the like, and generally limit the current spreading to neighboring channels which causes crosstalk. This better emulates the isolation between individual coax cables, and increases the isolation between neighboring differential signal traces 256-1, 256-2. This solution could be used on any signaling architecture to help reduce crosstalk. In general, the slit geometry is balanced such that crosstalk is suppressed while maintaining signal density and preventing other modes from forming. This can be optimized through three-dimensional electro-magnetic (EM) simulation, such as with a commercially available finite element program or the like. In example embodiments, there is a continuous ground plane where the flex cable is clamped to thermalize the entire flex (cable) when passing through a temperature stage in the cryostat. In example embodiments, reference planes can be shared between adjacently stacked striplines.

FIG. 2B illustrates a configuration (top view) of a flex cable featuring single-ended signals, in accordance with example embodiments. The flex cable of FIG. 2B includes single-ended patterned signal traces 280-1, 280-2. In example embodiments, the flex cable resides on a flexible dielectric (such as a polyimide). While two single-ended patterned signal traces 280-1, 280-2 are explicitly represented in FIG. 2B, an arbitrary number of single-ended patterned signal traces 280-1, 280-2 is contemplated. In example embodiments, CuNi, a low thermal conductivity material, is used for the reference ground planes 261-1, 261-2 that reside above (in some embodiments) and below the signal traces 280-1, 280-2 to help control thermal conductivity. Copper, for example, is used for the signal traces, such as the single-ended patterned signal traces 280-1, 280-2. (Other conductors, such as gold, silver, various alloys, and the like can also be utilized.) It is noted that, in example embodiments, reference ground planes 260-1, 260-2 also reside above the signal traces 280-1, 280-2, similar to the differential embodiments illustrated in FIGS. 3A-3C. In example embodiments, the reference ground planes 260-1, 260-2, 261-1, 261-2 that reside above (in some embodiments) and below the signal traces 280-1, 280-2 are connected by vias 264. Moreover, additional layers of signal traces 280-1, 280-2 and layers of reference ground planes 260-1, 260-2, 261-1, 261-2 may be stacked to create a flex cable having a plurality of signal trace layers interleaved with reference ground plane layers 260-1, 260-2, 261-1, 261-2. Each pair of reference ground planes 260-1, 260-2260-1, 260-2, 261-1, 261-2 in the multi-layer configuration can be connected by corresponding vias 264. As described above, to reduce crosstalk, reference ground plane slits 268 are integrated between signal traces 280-1, 280-2.

FIG. 3A illustrates a cross-sectional view of the CuNi reference ground planes having slits 268, in accordance with example embodiments. Signal traces 256-1, 256-2 reside between reference ground planes 260-1, 260-2 and reference ground planes 261-1, 261-2. In example embodiments, the reference ground planes 260-2, 261-2, 261-1, 261-2 that reside above and below the signal traces 256-1, 256 are connected by vias 264. In example embodiments, dielectric layers 276-1, 276-2 reside between the signal traces 256-1, 256 and the reference ground planes 260-1, 260-2, 261-1, 261-2, as illustrated in FIG. 3A.

FIG. 3B illustrates a cross-sectional view of the CuNi reference ground planes where the slits 268 are covered with CuNi, in accordance with example embodiments.

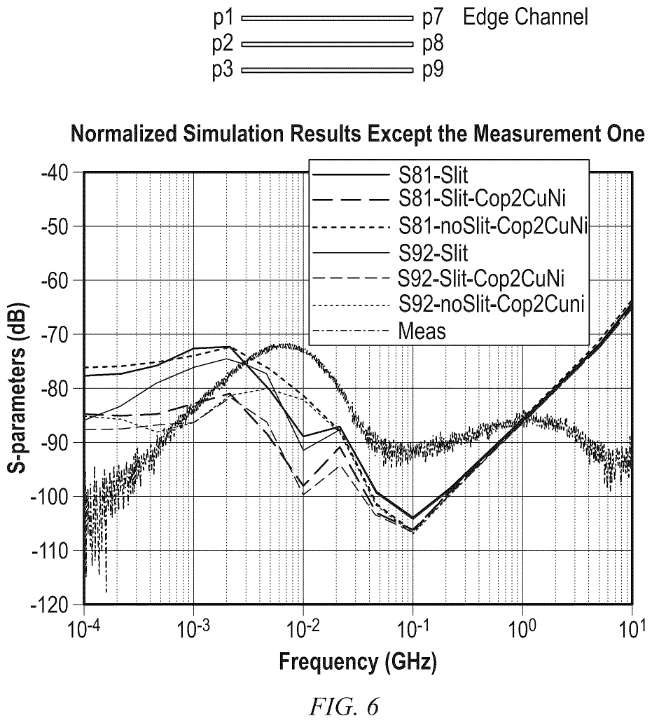

FIG. 3C illustrates a cross-sectional view of the CuNi reference ground planes where the slits 268 are covered and the planes are two times thicker than the embodiments of FIG. 3A and FIG. 3B, in accordance with example embodiments. A graph comparing crosstalk using the two times thicker reference ground planes is illustrated in FIG. 6.

FIG. 3D illustrates a cross-sectional view of a single CuNi reference ground plane having slits 268, in accordance with example embodiments. In example embodiments, the integrated radio frequency cable of FIGS. 2A-3C is implemented as one of a microstrip or co-planar waveguide. In the example embodiment of FIG. 3D, reference ground planes 260-1, 260-2 are not implemented and reference ground planes 261-1, 261-2 are utilized as described above. In addition, in example embodiments, a reference ground plane 263-1, 263-2 resides on the signal layer, that is, on the layer where signal traces 280-1, 280-2 reside, as depicted in FIG. 3D. The reference ground planes 263-1, 263-2 are connected to reference ground plane 261-2 using vias 264. While the embodiment of FIG. 3D features single-ended signal traces 280-1, 280-2, the use of differential signal traces 256-1, 256-2 is also contemplated.

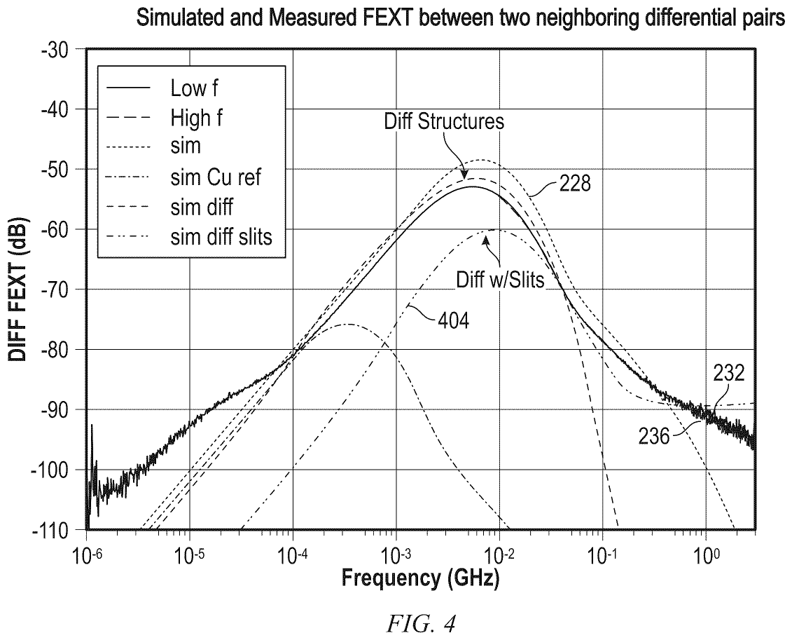

As illustrated in FIG. 1B, copper ground planes and traces meet the goal of −75 dB crosstalk. Moreover, as also illustrated in FIG. 1B, CuNi reference ground planes 260-1, 260-2, 261-1, 261-2 suffer from low frequency crosstalk as high as −50 dB. FIG. 4 is a plot illustrating the improvement to crosstalk at low frequency attained by using reference ground plane slits 268, in accordance with example embodiments. As illustrated in FIG. 4, differential signal traces 256-1, 256-2 with slit CuNi reference ground planes 260-1, 260-2, 261-1, 261-2 provide an ˜9 dB improvement in crosstalk (see line 404).

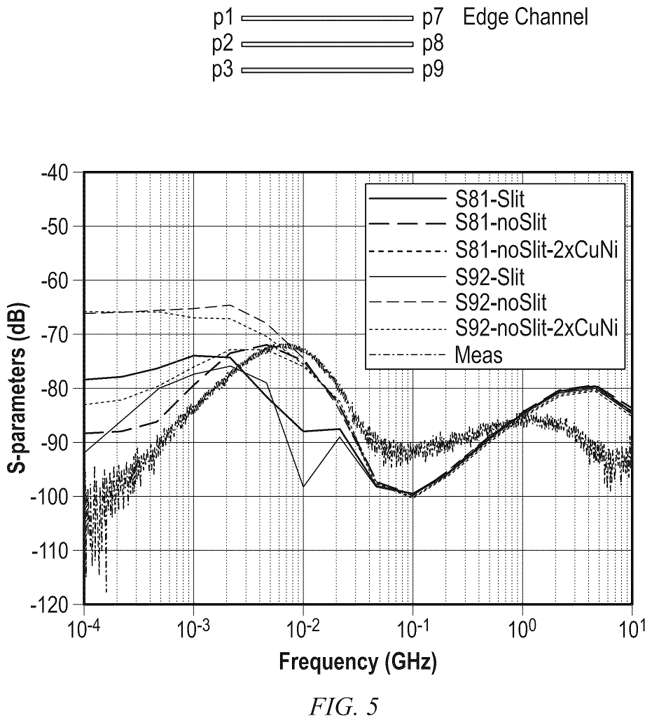

FIG. 5 is a graph comparing crosstalk for different embodiments, in accordance with example embodiments. In particular, FIG. 5 shows the crosstalk for embodiments with and without slits 268 for regular and double CuNi thickness reference ground planes (the traces refer to the port assignment, in accordance with the illustrated port map). Channel p1-p7 is for the edge channel (or channel 1) of the flex ribbon. The measurement is for S81 (as defined using scattering parameter notation where S81 refers to a transmission from port p1 to port p8 (solid lines for S81) and S92 refers to a transmission from port p2 to p9 (dashed lines for S92). As illustrated, the incorporation of slits 268 reduces the coupling. In addition, as illustrated in FIG. 5, the measured (Meas) and simulated (S81—noSlit) results are in good agreement.

FIG. 6 is a graph comparing crosstalk for different embodiments, in accordance with example embodiments. It is noted that thicker ground planes were utilized in the comparison of FIG. 6 (where the ground planes were twice as thick as the ground planes used in the comparison illustrated in FIG. 5 for the slit case). Channel p1-p7 is for the edge channel (or channel 1) of the flex ribbon. The differential signal traces 256-1, 256-2 are implemented using copper and the reference ground planes 260-1, 260-2 are implemented using CuNi. The simulation is for S81 (solid lines for S81, dashed lines for S92, both are normalized to S71). As illustrated, the incorporation of slits 268 and replacing signal copper to CuNi reduces the coupling.

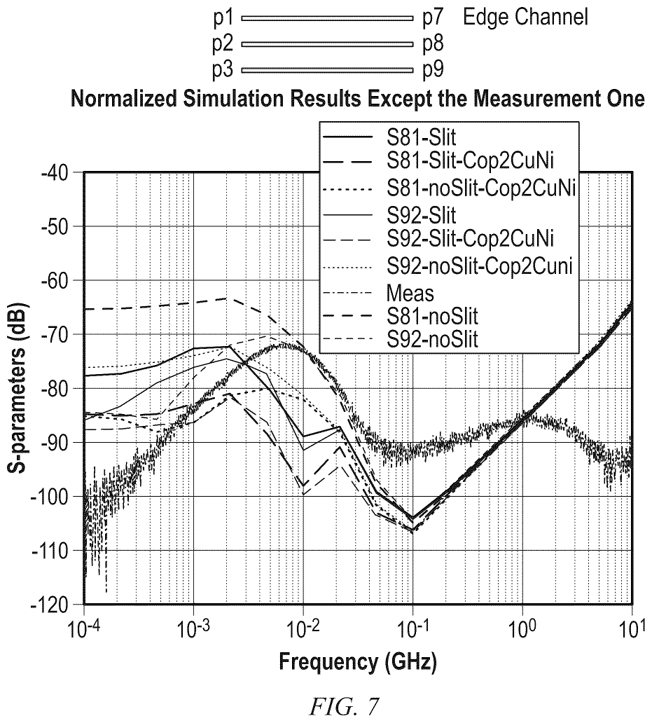

FIG. 7 is a graph comparing crosstalk for different embodiments, in accordance with example embodiments. Channel p1-p7 is for the edge channel (or channel 1) of the flex ribbon. The differential signal traces 256-1, 256-2 are implemented using copper and the reference ground planes 260-1, 260-2 are implemented using CuNi. The simulation is for S81 (solid lines for S81, dashed lines for S92, and both are normalized to S71). As illustrated, the incorporation of slits 268 and replacing signal copper to CuNi reduces the coupling, and increasing the reference CuNi ground plane thickness will not reduce the coupling.

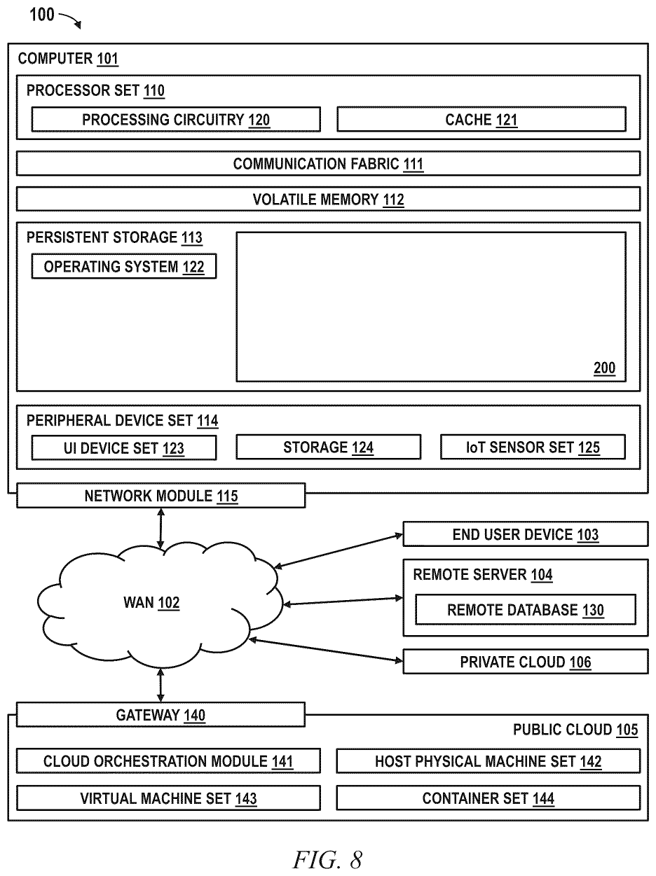

Refer now to FIG. 8.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as a system (see block 200) for semiconductor design and/or control of semiconductor fabrication (see FIG. 9). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 8. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

### Exemplary Design Process Used in Semiconductor Design, Manufacture, and/or Test

One or more embodiments make use of computer-aided semiconductor integrated circuit design simulation, test, layout, and/or manufacture. In this regard, FIG. 9 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 9 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 790 may then proceed to a stage 795 where, for example, design structure 790: proceeds to tape-out, is released to manufacturing, is released to a mask house, is sent to another design house, is sent back to the customer, etc.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A radio frequency cable comprising:
a first signal trace on a first signal layer of the radio frequency cable;
a first dielectric layer residing under the first signal layer; and
a first reference ground plane residing under the first dielectric layer of the radio frequency cable, the first dielectric layer separating the first reference ground plane and the first signal layer, the first reference ground plane having one or more slits defined therein, each slit running parallel to the first signal trace.

2. The radio frequency cable of claim 1, further comprising a second signal trace on the first signal layer of the radio frequency cable, the second signal trace running parallel to the first signal trace and the first signal trace and the second signal trace constituting a differential signal pair.

3. The radio frequency cable of claim 1, wherein the radio frequency cable is implemented as one of a microstrip, a stripline and a co-planar waveguide.

4. The radio frequency cable of claim 1, further comprising additional first signal traces on the first signal layer.

5. The radio frequency cable of claim 1, further comprising a second dielectric layer residing over the first signal layer and a second reference ground plane residing over the second dielectric layer of the radio frequency cable, the second reference ground plane having one or more slits defined therein, each slit running parallel to the first signal trace.

6. The radio frequency cable of claim 5, wherein the first reference ground plane and the second reference ground plane are implemented using CuNi.

7. The radio frequency cable of claim 5, further comprising one or more vias coupling the first reference ground plane to the second reference ground plane to prevent resonant modes between the first reference ground plane and the second reference ground plane.

8. The radio frequency cable of claim 5, further comprising:
a third signal trace on a second signal layer residing above the second reference ground plane of the radio frequency cable; and
a third reference ground plane residing above the second signal layer of the radio frequency cable, the third reference ground plane comprising one or more slits, each slit running parallel to the corresponding third signal trace.

9. A quantum computing system comprising:
a control electronics system;
a cryogenic quantum device; and
a signal delivery assembly between the control electronics system and the cryogenic quantum device, the signal delivery assembly comprising:
a first signal trace on a first signal layer of the radio frequency cable;
a first dielectric layer residing under the first signal layer; and
a first reference ground plane residing under the first dielectric layer of the printed circuit radio frequency cable, the first dielectric layer separating the first reference ground plane and the first signal layer, the first reference ground plane having one or more slits defined therein, each slit running parallel to the first signal trace.

10. The quantum computing system of claim 9, further comprising a cryogenic system configured to cool the cryogenic quantum device and wherein the signal delivery assembly transmits signals between two or more temperature stages of the cryogenic system.

11. The quantum computing system of claim 9, wherein the first reference ground plane is implemented using CuNi.

12. The quantum computing system of claim 9, wherein the cryogenic quantum device is a superconducting quantum processor.

13. The quantum computing system of claim 9, wherein the non-superconducting cables with the slits are concatenated with superconducting cables as part of the signal delivery assembly.

14. The quantum computing system of claim 9, further comprising a second signal trace on the first signal layer, the second signal trace running parallel to the first signal trace and the first signal trace and the second signal trace constituting a differential signal pair.

15. The quantum computing system of claim 9, wherein the signal delivery assembly is implemented as one of a microstrip, a stripline and a co-planar waveguide.

16. The quantum computing system of claim 9, further comprising a second dielectric layer residing over the first signal layer and a second reference ground plane residing over the second dielectric layer, the second reference ground plane having one or more slits defined therein, each slit running parallel to the first signal trace.

17. The quantum computing system of claim 16, wherein the first reference ground plane and the second reference ground plane are implemented using CuNi.

18. The quantum computing system of claim 16, further comprising one or more vias coupling the first reference ground plane to the second reference ground plane to prevent resonant modes between the first reference ground plane and the second reference ground plane.

19. The quantum computing system of claim 16, further comprising:
a third signal trace on a second signal layer residing above the second reference ground plane of the signal delivery assembly; and
a third reference ground plane on residing above the second signal layer of the signal delivery assembly, the third reference ground plane comprising one or more slits, each slit running parallel to the corresponding third signal trace.

20. The quantum computing system of claim 16, further comprising additional first signal traces on the first signal layer.
